(19) United States
(12) Patent Application Publication
(10) Pub. No.: US 2010/0308384 A1
(43) Pub. Date: Dec. 9, 2010

(54) METAL OXIDE SEMICONDUCTOR (MOS) SOLID STATE IMAGING DEVICE THAT INCLUDES A SURFACE LAYER FORMED BY IMPLANTING A HIGH CONCENTRATION OF IMPURITY DURING CREATION OF A PHOTODIODE, AND MANUFACTURING METHOD THEREOF

(76) Inventors: Morikazu TSUNO, Shiga (JP); Keishi TACHIKAWA, Toyama (JP)

Correspondence Address: MCDERMOTT WILL & EMERY LLP, 600 13TH STREET, NW, WASHINGTON, DC, 20005-3096, US

(21) Appl. No.: 12/768,428

(22) Filed: Apr. 27, 2010

(30) Foreign Application Priority Data
Jun. 9, 2009 (JP) 2009-138153

(51) Int. Cl. H01L 27/146; H01L 21/265

(52) U.S. Cl. 257/292; 438/73; 257/E21.334; 257/E27.133

(57) ABSTRACT

A photodiode has a carrier accumulation layer of a second conductivity type and a surface area of a first conductivity type deposited in order from an inside towards a surface of a first conductivity type well region. A transfer transistor is formed so that a transfer gate electrode of the transfer transistor partially overlaps the surface layer of the photodiode and is formed above a surface of the first conductivity type well region with a gate insulating film therebetween. The surface layer includes a first surface layer, which partially overlaps the transfer gate electrode in the direction of the x-axis, and a second surface layer adjacent to the first surface layer. A concentration of the impurity of the first conductivity type is higher in the second surface layer than in the first surface layer.

The disclosure of Japanese Patent Application No. 2009-138153 filed Jun. 9, 2009 including specification, drawings and claims is incorporated herein by reference in its entirety.

### BACKGROUND OF THE INVENTION

(1) Field of the Invention

The present invention relates to an MOS solid state imaging device and a manufacturing method thereof, and in particular to the structure of the surface layer of a photodiode.

(2) Description of the Related Art

Solid state imaging devices used in digital cameras and the like are widely divided into two types: charge coupled device (CCD) solid state imaging devices and metal oxide semiconductor (MOS) solid state imaging devices. Since an MOS solid state imaging device first amplifies, inside each unit pixel, a charge signal that a photodiode generates by photoelectric conversion and then outputs the charge signal, an MOS solid state imaging device has the advantage of being more sensitive than a CCD solid state imaging device. The structure of an MOS solid state imaging device (hereinafter, simply referred to as “solid state imaging device”) according to conventional technology is described with reference to FIGS. 1A and 1B.

As shown in FIG. 1A, a unit pixel 90 in a solid state imaging device has a photodiode 901 and four transistors (transfer transistor 902, reset transistor 903, amplification transistor 904, and select transistor 905). A drain in the transfer transistor 902 is a floating diffusion (hereinafter, “FD”) 906. While omitted from the figures, around the photosensitive region, in which a plurality of unit pixels 90 are arranged, a vertical and a horizontal shift transistor and a pulse generating circuit are formed.

FIG. 1B shows the photodiode 901 and transfer transistor 902 in the unit pixel 90. As shown in FIG. 1B, the semiconductor substrate 910 is formed with a p-type well region 912 on an n-type substrate base 911. Each unit pixel 90 is formed by the area partitioned by isolation regions 913 and 914 formed on the surface section of the well region 912. The photodiode 901 is formed in the region 90a, inwards from the surface side of the well region 912, by a combination of a surface layer 916 that includes a p-type impurity and a charge accumulation layer 915 that includes an n-type impurity.

At the region 90b, a gate insulating film 919 and a transfer gate electrode 920 are layered on the surface of the well region 912 so as to partially overlap the charge accumulation layer 915 of the photodiode 901. The charge accumulation layer 915 of the photodiode 901 is the source of the transfer transistor 902, and the drain (FD 906) of the transfer transistor 902 is formed by an FD low concentration n-type impurity region 921 located near the transfer gate electrode 920 and an FD high concentration n-type impurity region 923 electrically connected to the FD low concentration n-type impurity region 921.

An overlying film 924 covers the photodiode 901, and a side wall 922 covers the side of the transfer gate electrode 920.

During driving of the solid state imaging device, a signal charge is generated by photoelectric conversion in the photodiode 901 formed by a p-n junction, and the charge signal (electrons) that accumulate at the p-n junction of the photodiode 901 are transferred to the FD 906 when the transfer transistor 902 is turned on. The transferred signal charge is amplified by the amplification transistor 904 and output via the select transistor 905.

In this configuration, during formation of the surface layer 916 of the photodiode 901, a p-type impurity is implanted with the transfer gate electrode 920 as a mask (see, for example, U.S. Pat. No. 6,504,193). Implantation of the p-type impurity to form the surface layer 916 is performed at a relatively high concentration. This is because if the surface layer 916 is formed at a low concentration, the depletion layer will reach the surface of the semiconductor substrate 910, increasing susceptibility to the effects of a surface state, which leads to an increase in dark current. A high concentration is used to suppress this effect.

As shown in FIG. 2A, when forming the surface layer 927 of the photodiode 907 by implanting a high concentration of a p-type impurity with the transfer gate electrode 920 as a mask, the surface layer 927 and the transfer gate electrode 920 end up having an overlapping section. When the surface layer 927 and the transfer gate electrode 920 have an overlapping section due to implantation of a high concentration of a p-type impurity, white spots increase. When white spots increase, then as compared to the potential distribution (FIG. 2C) of the central section (section D of FIG. 2A) of the transfer gate electrode 920, at the edge of the transfer gate electrode 920 (section C in FIG. 2A), the width W of the depletion layer becomes narrow, as shown in FIG. 2B, since the concentration of the p-type impurity is high. For this reason, at the edge of the transfer gate electrode 920, the curve of the band (conduction band Ec, valence band Ev) at the substrate surface becomes greater, and thus leakage current occurs due to interband tunneling. The occurrence of leakage current via interband tunneling causes the electric potential of the FD 906 to lower, thus leading to an increase in white spots, as described above.

With the objective of suppressing this sort of occurrence of leakage current via interband tunneling at the edge of the transfer gate electrode 920, technology has been proposed to form the surface layer at a position removed from the edge of the transfer gate electrode 920 by implanting, with the transfer gate electrode 920 as a mask, the high concentration of p-type impurity at an angle (see, for example, Tokuhyo (published Japanese translation of PCT international publication for patent application) No. 2007-500444). In other words, as shown in FIG. 1B, it is proposed in Tokuhyo No. 2007-500444 to suppress the occurrence of white spots by forming the surface layer 916 of the photodiode 901 with an interval g3 before the transfer gate electrode 920.

However, in a solid state imaging device formed using the technology proposed in Tokuhyo No. 2007-500444, as shown in FIG. 1B, the surface layer 916 of the photodiode 901 and the transfer gate electrode 920 are formed at locations removed from each other. Therefore, the charge accumulation layer 915 is exposed on the surface between the surface layer 916 and the transfer gate electrode 920. The depletion layer across the p-n junction thereby reaches the surface of the semiconductor substrate 910 (well region 912), and the effect of a surface state causes the problem of dark current being easily produced. In a solid state imaging device according to the above-described conventional technology, the same problems occur even when the region formed by a p-type conductive type and the region formed by an n-type conductive type are reversed.

### SUMMARY OF THE INVENTION

It is an object of the present invention to solve the above problems by providing a solid state imaging device that can suppress the occurrence of both dark current and white spots and a manufacturing method thereof.

To achieve the above-described object, the present invention adopts the following structure.

The solid state imaging device according to the present invention includes a photodiode and a transfer transistor as structural elements. The photodiode is capable of photoelectric conversion and is formed in a well region of a semiconductor substrate, the well region including an impurity of a first conductivity type. The transfer transistor is capable of reading a charge from the photodiode and is formed to have a transfer gate electrode above a surface of the well region with a gate insulating film therebetween.

In the solid state imaging device according to the present invention, in the photodiode a carrier accumulation layer and a surface layer are deposited in order from an inside towards a surface of the well region in a direction of thickness, the carrier accumulation layer including an impurity of a second conductivity type (opposite to the first conductivity type) and the surface layer including the impurity of the first conductivity type. Also, the transfer transistor is formed so that the transfer gate electrode partially overlaps the surface layer of the photodiode.

In the solid state imaging device according to the present invention as described above, the surface layer of the photodiode includes a first surface layer that partially overlaps the transfer gate electrode and a second surface layer that does not overlap the transfer gate electrode. The first surface layer and the second surface layer are adjacent to each other in a direction parallel to the surface of the well region, and a concentration of the impurity of the first conductivity type is higher in the second surface layer than in the first surface layer.

In the above structure, one of the first conductivity type and the second conductivity type is p-type, and the other is n-type.

In the solid state imaging device according to the present invention, the surface layer in the photodiode includes a first surface layer and a second surface layer, and whereas the first surface layer overlaps the transfer gate electrode, the second surface layer does not. The first surface layer and second surface layer are both regions that include an impurity of a first conductivity type, and in the solid state imaging device according to the present invention with this structure, the carrier accumulation layer in the photodiode, which includes an impurity of the second conductivity type, does not appear on the surface of the semiconductor substrate near the edge of the transfer gate electrode. Therefore, the depletion layer does not reach the surface of the semiconductor substrate (surface of the well region). Accordingly, in the solid state imaging device according to the present invention, since the depletion layer across the p-n junction does not appear on the surface of the semiconductor substrate, the occurrence of dark current due to the effects of a surface state is suppressed.

Furthermore, in the solid state imaging device according to the present invention, the first surface layer is formed by self-alignment with regards to the transfer gate electrode and therefore can stably suppress production of dark current.

Also, in the solid state imaging device according to the present invention, the concentration of impurity of the first conductivity type is higher in the second surface layer than in the first surface layer. In other words, in the solid state imaging device according to the present invention, the second surface layer having a higher concentration of impurity of the first conductivity type does not overlap the transfer gate electrode. Therefore, in the solid state imaging device according to the present invention, the width of the depletion layer at the edge of the transfer gate electrode does not become narrow, and the curve of the band does not become greater, which thus suppresses the occurrence of leakage current due to interband tunneling. Accordingly, the solid state imaging device according to the present invention also suppresses the occurrence of white spots.

Consequently, the solid state imaging device according to the present invention suppresses the occurrence of both dark current and white spots and has high S/N characteristics in the circuitry.

A method of manufacturing a solid state imaging device according to the present invention includes the following steps.

(S1) A well region formation step to form a well region by implanting an impurity of a first conductivity type inwards from one surface of a semiconductor substrate.

(S2) A carrier accumulation layer formation step to form a carrier accumulation layer of a photodiode by implanting an impurity of a second conductivity type opposite to the first conductivity type inside the well region.

(S3) A transfer gate electrode formation step to form a transfer gate electrode of a transfer transistor above a surface of the well region so as to partially overlap the carrier accumulation layer.

(S4) A first surface layer formation step to form a first surface layer of the photodiode by implanting the impurity of the first conductivity type inwards from a surface of the well region in which the carrier accumulation layer is formed, so that a section of the first surface layer is positioned under the transfer gate electrode.

(S5) A second surface layer formation step to form a second surface layer by implanting the impurity of the first conductivity type inwards from a surface of the well region in which the carrier accumulation layer is formed, so that the second surface layer does not overlap the transfer gate electrode and is adjacent to the first surface layer.

Also, in the method of manufacturing a solid state imaging device according to the present invention, a concentration of the impurity of the first conductivity type is higher in the second surface layer than in the first surface layer.

Also, in the method of manufacturing a solid state imaging device according to the present invention, in the photodiode, the second surface layer is formed deeper than the first surface layer.

Note that in the above structure, one of the first conductivity type and the second conductivity type is p-type, and the other is n-type.

The above-described solid state imaging device according to the present invention can be manufactured with the above method of manufacturing according to the present invention. Accordingly, a solid state imaging device that suppresses the occurrence of both dark current and white spots and has high S/N characteristics in the circuitry can be manufactured with the above method of manufacturing.

Note that also in the solid state imaging device according to conventional technology shown in FIG. 1B, it is plausible to form a region with a low concentration of an impurity of a first conductivity type (p-type) in the section adjacent to the surface layer 916. In the solid state imaging device according to the present invention, however, the concentration of the impurity of the first conductivity type in the first surface area is higher than this adjacent section.

In the solid state imaging device according to the present invention and the manufacturing method thereof, the following variations may, for example, be adopted.

In the above-described solid state imaging device according to the present invention and manufacturing method thereof, in the first surface layer in the photodiode, the concentration of the impurity of the first conductivity type in the section overlapping the transfer gate electrode may be in a range of 1E18/cm³ or greater and 1E19/cm³ or less.

In the above-described solid state imaging device according to the present invention and manufacturing method thereof, in the second surface layer in the photodiode, a maximum concentration of the impurity of the first conductivity type may be 2E19/cm³ or greater.

In the above-described solid state imaging device according to the present invention and manufacturing method thereof, the second surface layer in the photodiode may be formed at a distance of 50 nm or greater from the transfer gate electrode.

In the above-described solid state imaging device according to the present invention and manufacturing method thereof, a depth of the second surface layer in the photodiode from the surface of the well region may be greater than the first surface region.

In the above-described method of manufacturing a solid state imaging device according to the present invention, the impurity of the first conductivity type may be implanted at a larger dose during the second surface layer formation step than a dose of the impurity of the first conductivity type implanted during the first surface layer formation step.

### BRIEF DESCRIPTION OF THE DRAWINGS

These and the other objects, advantages and features of the invention will become apparent from the following description thereof taken in conjunction with the accompanying drawings which illustrate a specific embodiment of the invention.

In the drawings:

FIG. 1A is a circuit diagram showing a unit pixel 90 in a solid state imaging device according to conventional technology;

FIG. 1B is a cross-section diagram showing the positional relationship between the transfer gate electrode 920 and the photodiode 901 in the unit pixel 90;

FIG. 2A is a cross-section diagram showing a unit pixel in which the concentration of a p-type impurity in a surface layer 927 of a photodiode 907 is high, and in which the transfer gate electrode 920 partially overlaps the surface layer 927;

FIG. 2B is a potential distribution diagram for the structure shown in FIG. 2A;

FIG. 2C is a potential distribution diagram for the structure shown in FIG. 2A;

FIG. 3 is a block diagram schematically showing the overall structure of a solid state imaging device 1 according to the embodiment;

FIG. 4 is a circuit diagram showing a unit pixel 10 in the solid state imaging device 1;

FIG. 5 is a cross-sectional diagram schematically showing the structure of a photodiode 101 and a transfer transistor 102 in the unit pixel 10;

FIG. 6A is a cross-sectional diagram schematically showing part of the manufacturing process of the solid state imaging device 1;

FIG. 6B is a cross-sectional diagram schematically showing part of the manufacturing process of the solid state imaging device 1;

FIG. 6C is a cross-sectional diagram schematically showing part of the manufacturing process of the solid state imaging device 1;

FIG. 7A is a cross-sectional diagram schematically showing part of the manufacturing process of the solid state imaging device 1;

FIG. 7B is a cross-sectional diagram schematically showing part of the manufacturing process of the solid state imaging device 1;

FIG. 7C is a cross-sectional diagram schematically showing part of the manufacturing process of the solid state imaging device 1;

FIG. 8 is a cross-sectional diagram schematically showing part of the manufacturing process of the solid state imaging device 1;

FIG. 9A is a planar view schematically showing the shape of a resist mask 501 used in the manufacturing process of the photodiode 101;

FIG. 9B is a planar view schematically showing the shape of a resist mask 502 used in the manufacturing process of the photodiode 101;

FIG. 10 is a characteristic diagram showing the relationship between interband tunneling current Id and the number of white spots; and

FIG. 11 is a characteristic diagram showing the relationship between interband tunneling current Id and concentration of impurity at the edge of the gate on the transfer transistor side.

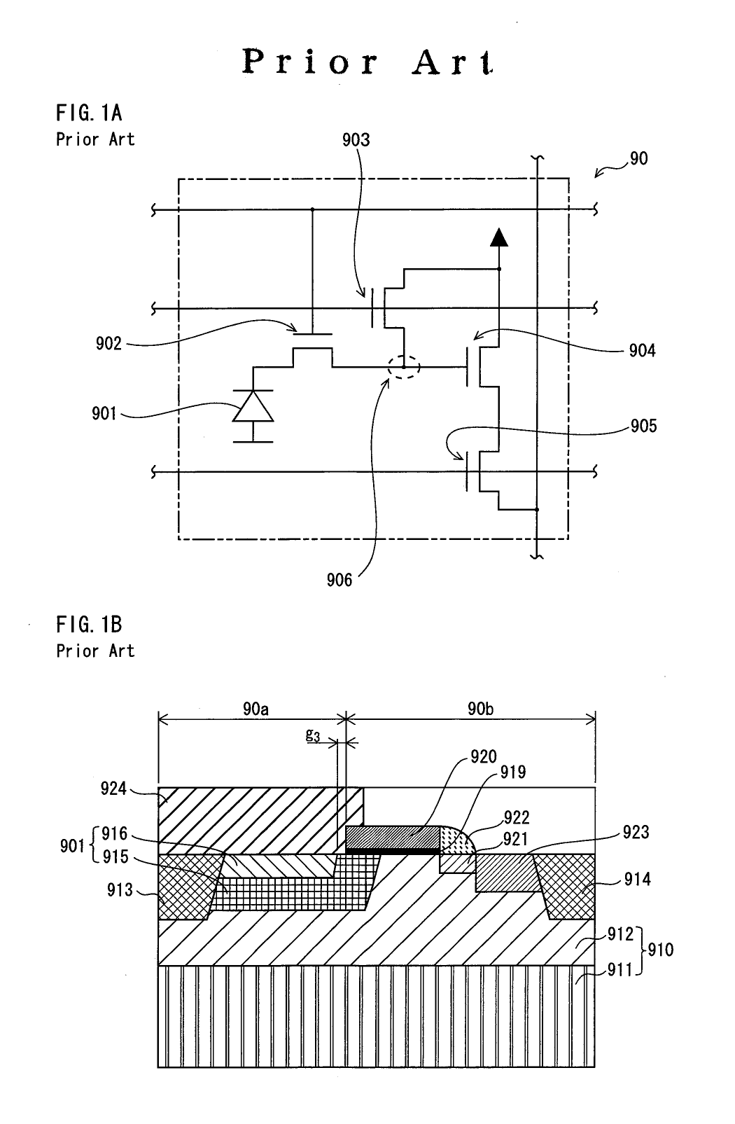

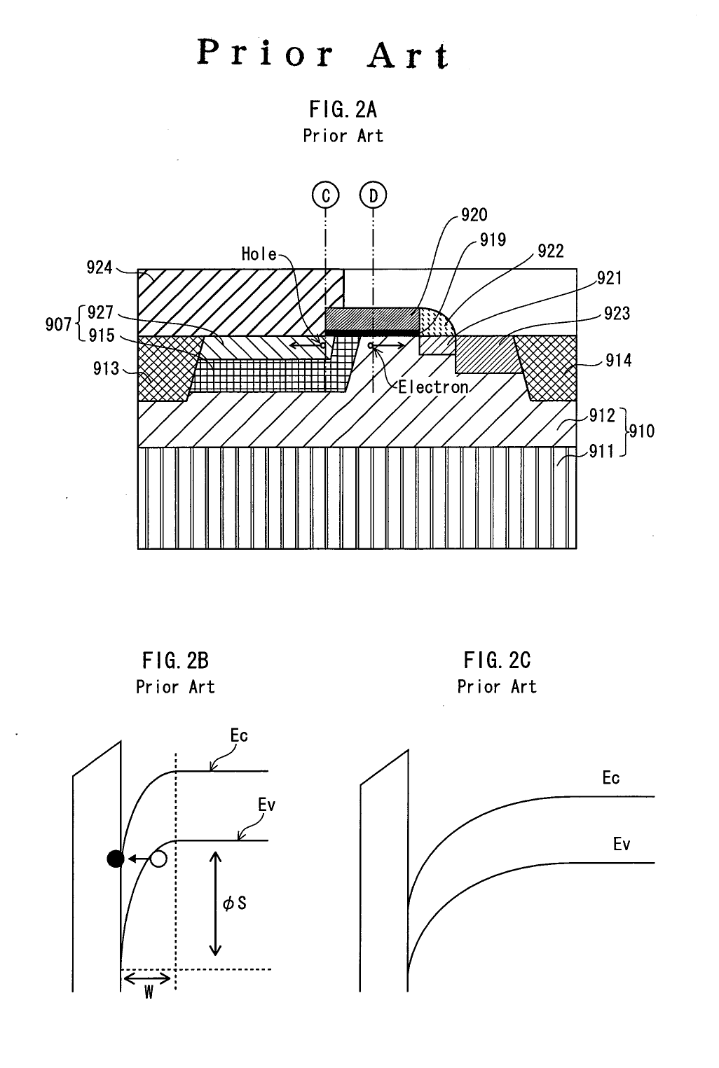

### DESCRIPTION OF THE PREFERRED EMBODIMENT

The following describes a preferred embodiment for implementing the present invention with reference to the drawings. Note that the following embodiment is only an example used to clearly illustrate the structure of the present invention and the effects and advantages derived therefrom; apart from its essential characteristics, the present invention is in no way limited to the following embodiment.

### Embodiment

### 1. Overall Structure of the Solid State Imaging Device 1

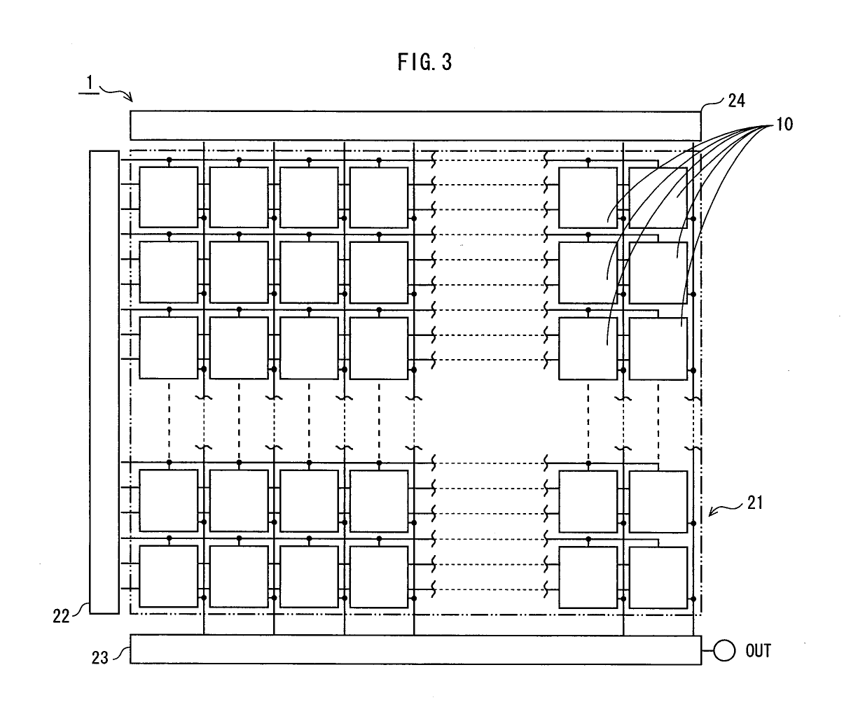

The overall structure of a solid state imaging device 1 according to the present embodiment is described with reference to FIG. 3. The solid state imaging device shown in FIG. 3 is, for example, an MOS solid state imaging device used as an image input device in a digital still camera, digital movie camera, etc.

As shown in FIG. 3, the solid state imaging device 1 according to the present invention is composed of a photosensitive region 21 formed by a plurality of unit pixels 10 and of a peripheral circuit unit that surrounds the photosensitive region 21 and drives the unit pixels 10 in the photosensitive region 21. A vertical shift register 22, horizontal shift register 23, and pulse generating circuit 24 are included in the peripheral circuit unit.

In the photosensitive region 21, a plurality of unit pixels 10 are disposed in a two-dimensional matrix and are connected to the peripheral circuit unit that includes the vertical shift register 22, horizontal shift register 23, and pulse generating circuit 24.

The vertical shift register 22 and horizontal shift register 23 are, for example, both dynamic circuit units that respond to impression of a timing pulse from the pulse generating circuit 24 and output, in order, a driving pulse to each unit pixel 10.

### 2. Structure of Unit Pixel 10

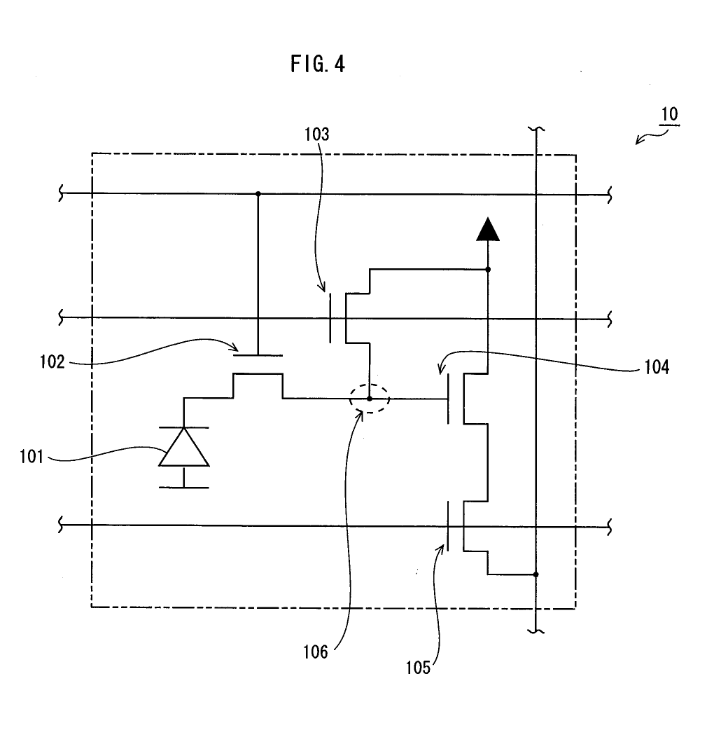

The structure of the unit pixel 10 in the solid state imaging device 1 is described with reference to FIG. 4.

As shown in FIG. 4, the unit pixel 10 is an amplifying unit pixel. The unit pixel 10 has a photodiode 101 and four transistors (transfer transistor 102, reset transistor 103, amplification transistor 104, and select transistor 105). A drain in the transfer transistor 102 is a floating diffusion (hereinafter, “FD”) 106.

As shown in FIG. 4, between adjacent unit pixels 10, the gate electrodes of transfer transistors 102, the gate electrodes of reset transistors 103, and the gate electrodes of select transistors 105 are connected via a wiring line that extends horizontally through each unit pixel 10. Furthermore, between vertically adjacent unit pixels 10, the drains of select transistors 105 are connected via a wiring line that extends horizontally through each unit pixel 10.

The photodiode 101 is a component having a photoelectric conversion function that generates a signal charge in accordance with the strength of light that enters each unit pixel 10. One terminal of the photodiode 101 is grounded, and the other terminal is connected to the source of the transfer transistor 102. The transfer transistor 102 is a component that detects and transfers, to its own drain, the charge signal generated by the photoelectric conversion function of the photodiode 101. The drain is connected to the gate of the amplification transistor 104 and to the source of the reset transistor 103.

The reset transistor 103 is a component to reset, at a preset, fixed time interval, the signal charge accumulated in the drain of the transfer transistor 102. The drain of the reset transistor 103 is connected electrically to a power supply voltage VDD. The amplification transistor 104 is a component that, when the select transistor 105 is turned on in accordance with a signal from the vertical shift register 22, outputs the signal charge accumulated in the FD 106, i.e. the drain of the transfer transistor 102. The drain of the amplification transistor 104 is connected to the power supply voltage VDD, and the source is connected to the drain of select transistor 105.

In the unit pixel 10, among the four transistors 102-105, the amplification transistor 104 fulfills the function of amplifying the signal charge, and the other transistors 102-103 and 105 fulfill the function of switching.

### 3. Structure of the Photodiode 101 and Transfer Transistor 102

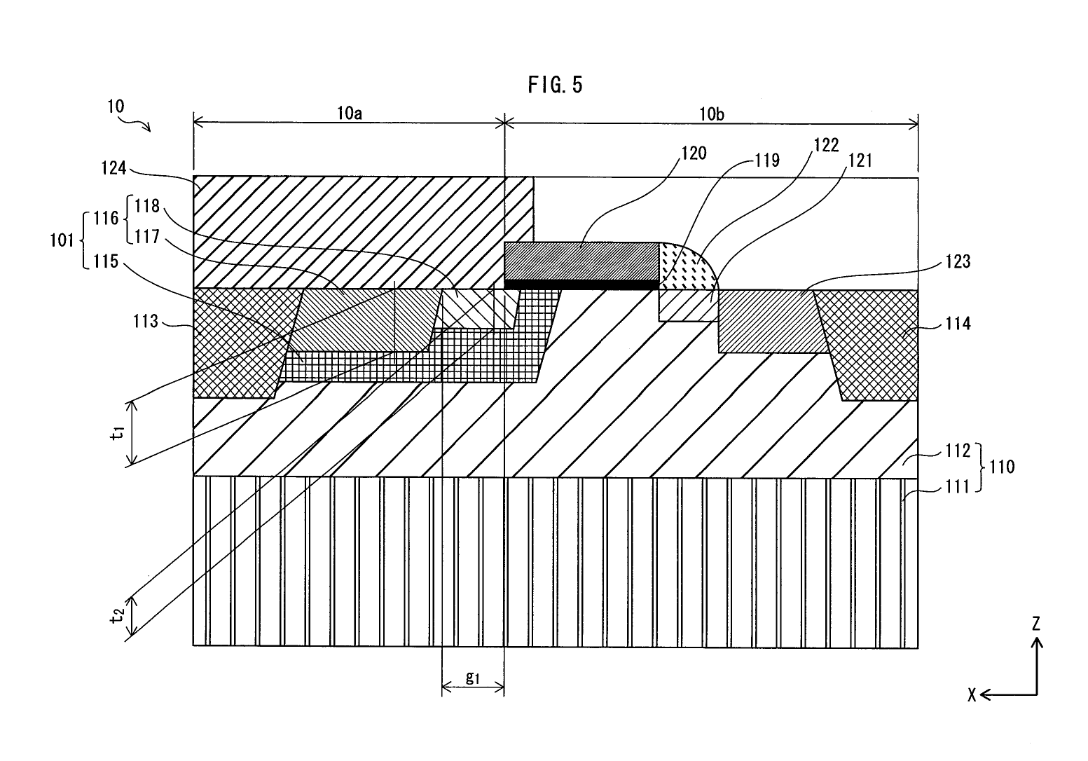

The structure of the photodiode 101 and the transfer transistor 102 in the unit pixel 10 in the solid state imaging device 1 is described with reference to FIG. 5, which is a cross-sectional diagram schematically showing the structure of the photodiode 101 and the transfer transistor 102 in the unit pixel 10.

As shown in FIG. 5, the pixel unit 10 in the solid state imaging device 1 is formed with a semiconductor substrate 110 as a base, the semiconductor substrate 110 being formed by an n-type substrate base 111 and a p-type well region 112 formed above the n-type substrate base 111 along the z-axis. Each unit pixel 10 is formed by an area partitioned by isolation regions 113 and 114 formed on the surface section of the well region 112. The photodiode 101 is formed in the region 10a, inwards from the surface side of the well region 112, by a combination of a surface layer 116 that includes a p-type impurity and a charge accumulation layer 115 that includes an n-type impurity.

The isolation regions 113 and 114 have a shallow trench isolation (STI) structure.

At the region 10b, a gate insulating film 119 and a transfer gate electrode 120 are layered on the surface of the well region 112 so as to partially overlap the charge accumulation layer 115 and the surface layer 116 of the photodiode 101. The charge accumulation layer 115 of the photodiode 101 is the source of the transfer transistor 102, and the drain (FD 106) of the transfer transistor 102 is formed by an FD low concentration n-type impurity region 121 located near the transfer gate electrode 120 and an FD high concentration n-type impurity region 123 electrically connected to the FD low concentration n-type impurity region 121. An overlying film 124 covers the photodiode 101, and a side wall 122 covers the side of the transfer gate electrode 120.

The gate insulating film 119 is formed by a silicon oxide film having a film thickness of roughly 5 nm to 10 nm. The transfer gate electrode 120 is formed by a conductive polysilicon film having a film thickness of roughly 140 nm to 200 nm.

Furthermore, the charge accumulation layer 115 of the photodiode 101 is a region that includes an n-type impurity such arsenic (As), phosphorus (P), antimony (Sb), etc. On the other hand, the surface layer 116 of the photodiode 101 is a region that includes a p-type impurity such as boron (B), indium (In), etc.

In this embodiment, in the unit pixel 10 in the solid state imaging device 1, the surface layer 116 in the photodiode 101 is formed to include a first surface layer 118 and a second surface layer 117 that are formed adjacent to each other along the x-axis. A section at the right edge of the first surface layer 118 overlaps the transfer gate electrode 120. Conversely, the second surface layer 117 is separated from the transfer gate electrode 120 by an interval g1 and is formed so as to be in contact with the first surface layer 118. The interval g1 between the transfer gate electrode 120 and the second surface layer 117 is set to be 50 nm or more and roughly 120 nm to 130 nm or less.

As compared to the first surface layer 118, the second surface layer 117 in the photodiode 101 has a higher concentration of a p-type impurity. Specifically, the maximum concentration of the p-type impurity in the second surface layer 117 is 3E19/cm³. On the other hand, the concentration of the p-type impurity in the first surface layer 118 is, at the section overlapping the transfer gate electrode 120, a maximum of 1E18/cm³.

Furthermore, the second surface layer 117 is formed at a film thickness t1 (for example, 120 nm to 180 nm), and the formational thickness, with the surface of the well region 112 as a reference, is deeper than the first surface layer 118, which is formed at a film thickness t2 (for example, 60 nm to 80 nm).

### 4. Advantages

In the solid state imaging device 1 according to the present embodiment, the surface layer 116 in the photodiode 101 is formed by a first surface layer 118 and a second surface layer 117, and a section at the right edge of the first surface layer 118 along the x-axis overlaps the transfer gate electrode 120. Furthermore, the second surface layer 117 does not overlap the transfer gate electrode 120, but rather is separated by an interval g1.

The first surface layer 118 and the second surface layer 117 in the photodiode 101 are both areas that include a p-type impurity. In the solid state imaging device 1 having this structure, the charge accumulation layer 115 that includes an n-type impurity does not appear on the surface of the semiconductor substrate 110 near the edge of the transfer gate electrode 120, and therefore the depletion layer does not reach the surface of the semiconductor substrate 110 (the surface of the well region 112). Accordingly, in the solid state imaging device 1, since the depletion layer across the p-n junction does not appear on the surface of the semiconductor substrate 110, the occurrence of dark current due to the effects of a surface state is suppressed.

Also, in the solid state imaging device 1 according to the present embodiment, the concentration of the p-type impurity is higher in the second surface layer 117 than in the first surface layer 118. Therefore, the width of the depletion layer at the edge of the transfer gate electrode 120 does not become narrow, and the curve of the band does not become greater, which thus suppresses the occurrence of leakage current due to interband tunneling. Accordingly, the solid state imaging device 1 also suppresses the occurrence of white spots.

Consequently, the solid state imaging device 1 according to the present embodiment suppresses the occurrence of both dark current and white spots and has high S/N characteristics in the circuitry.

Note that in the second surface layer 117 in the photodiode 101, it suffices for the concentration of the p-type impurity to be 2E19/cm³ or more and for the concentration of the p-type impurity in the first surface layer 118 to be in a range of 1E18/cm³ or more and 1E19/cm³ or less.

### 5. Manufacturing Method of the Solid State Imaging Device 1

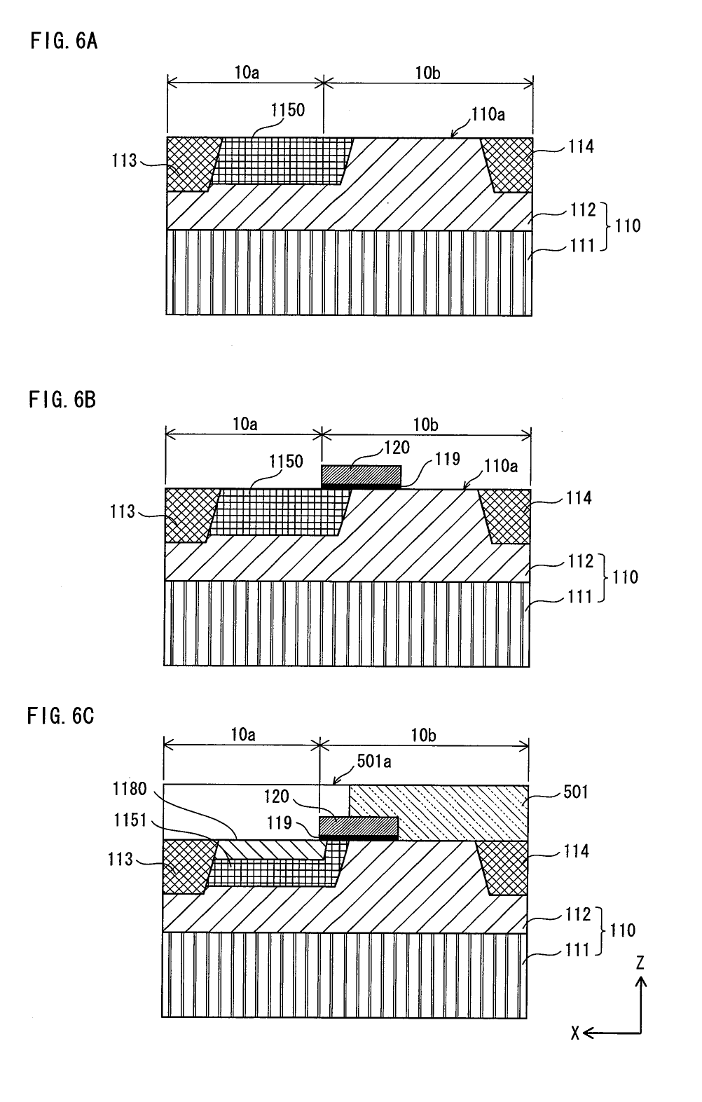

Next, the parts of the manufacturing method relating to the characteristics of the solid state imaging device 1 according to the present embodiment are described with reference to FIGS. 6A-9B.

First, as shown in FIG. 6A, a widely known method is used for the n-type substrate surface, and the isolation regions 113 and 114 are formed. As described above, the isolation regions 113 and 114 have an STI structure. After formation of the isolation regions 113 and 114, the p-type well region 112 is formed in the region 10a, a preparatory region in which the photodiode will be formed, and the region 10b, a preparatory region in which the transfer transistor will be formed. The semiconductor substrate 110 is thus formed from an n-type substrate base 111 and a p-type well region 112. On the main surface 110a above the semiconductor substrate 110 along the z-axis, a mask (omitted from the figures) having an opening at the region 10a is disposed, and by using an ion implantation method that passes through this mask, a charge accumulation preparatory layer 1150 that includes an n-type impurity is formed in the region 10a.

The implantation requirements for the n-type impurity during formation of the charge accumulation preparatory layer 1150 are as follows.

(1) Dose: 3.7E12/cm²

(2) Implantation energy: 350 keV

(3) Implanted element: one of arsenic (As), phosphorus (P), and antimony (Sb)

The charge accumulation preparatory layer 1150 is formed under the above-stated requirements, and the concentration of the p-type impurity becomes roughly 2E17/cm³.

Next, as shown in FIG. 6B, the gate insulating film 119 is formed on the main surface 110a of the semiconductor substrate 110. Note that in FIG. 6B and other figures, the gate insulating film 119 is formed on only a part of the main surface 110a of the semiconductor substrate 110, yet the gate insulating film 119 can be formed on the entire surface. The gate insulating film 119 has a film thickness of roughly 5 nm to 10 nm and is formed by oxidizing the main surface 110a of the semiconductor substrate 110 via a thermal oxidation method. Above the gate insulating film 119, a conductive polysilicon film having a film thickness of roughly 140 nm to 200 nm is formed by a reduced pressure chemical vapor deposition (CVD) method or the like. On this polysilicon film, the transfer gate electrode 120 for the transfer transistor 102 is formed, as shown in FIG. 6B, with widely known photolithography technology and etching technology.

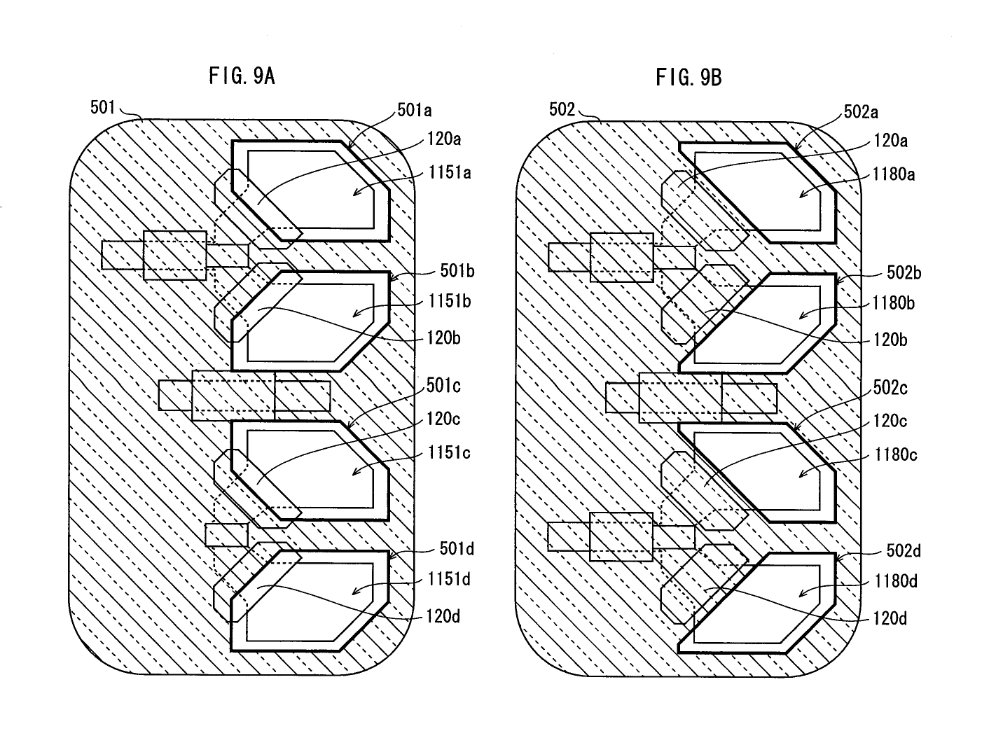

Next, as shown in FIG. 6C, a resist mask 501 is deposited, the resist mask 501 having an opening 501a that extends from a position located a predetermined interval from the edge of the source side of the transfer gate electrode 120 for the transfer transistor 102 to the isolation region 113, which defines the edge of the region 10a (the source region of the transfer transistor 102). The resist mask 501 is formed with widely known photolithography technology. As shown in FIG. 9A, in this embodiment, openings 501a, 501b, 501c, 501d, etc. in the resist mask 501 are established in each region corresponding to each unit pixel 10 so that the charge accumulation layers 1151a, 1151b, 1151c, 1151d, etc. are exposed. Part of the opening edge is located above the transfer gate electrodes 120a, 120b, 120c, 120d, etc.

Returning to FIG. 6C, a p-type impurity is ion implanted inwards from the surface of the charge accumulation preparatory layer 1150 through the opening 501a of the resist mask 501 formed as described above. In this way, in the thickness direction of the semiconductor substrate 110, a first surface preparatory layer 1180, which is a p-type impurity region, can be formed on a charge accumulation preparatory layer 1151. The implantation requirements for the p-type impurity during formation of the first surface preparatory layer 1180 are as follows.

(1) Dose: 2E13/cm²

(2) Implantation energy: 3 keV

(3) Implanted element: boron (B) or indium (In)

The first surface preparatory layer 1180 is formed under the above-stated requirements, and the maximum concentration of the impurity in the section overlapping the transfer gate electrode 120 becomes roughly 1E18/cm³.

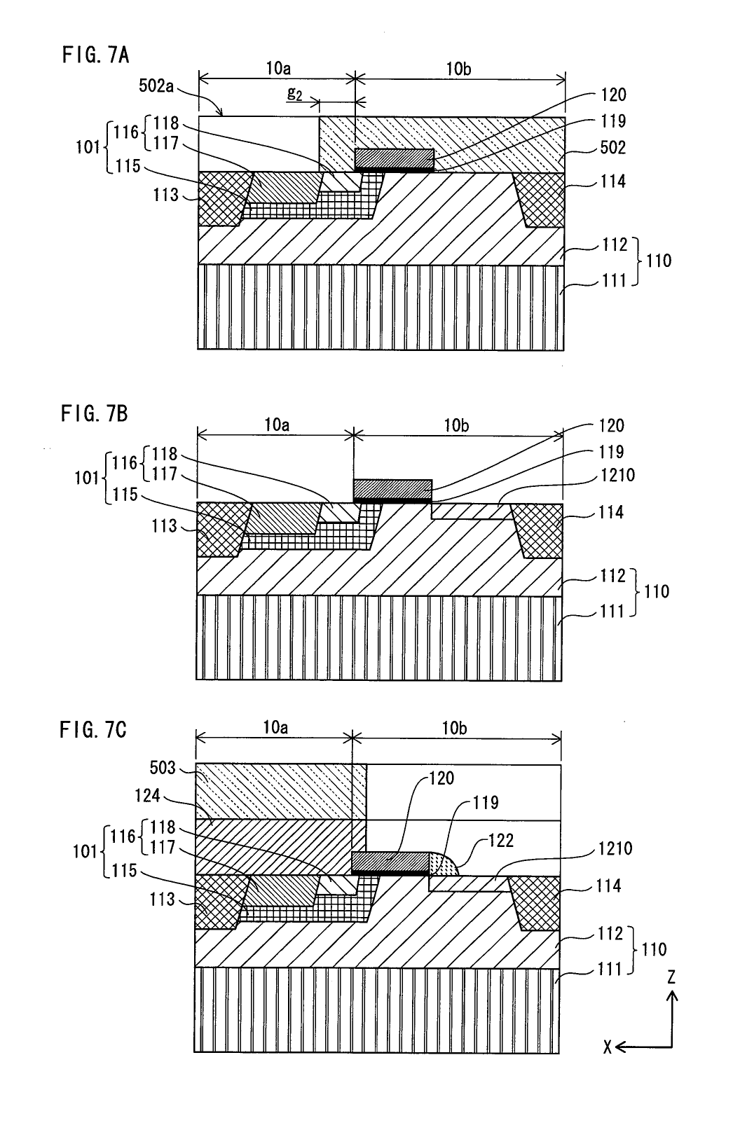

Next, as shown in FIG. 7A, a resist mask 502 is deposited so as to cover the entire region 10b, which includes the transfer gate electrode 120, and part of the region 10a. The resist mask 502 has an opening 502a that extends from a position located an interval g2 from the edge of the photodiode 101 side of the transfer gate electrode 120 to the isolation region 113, which defines the edge of the region 10a (the source region of the transfer transistor 102).

As shown in FIG. 9B, part of each of the first surface preparatory layers 1180a, 1180b, 1180c, 1180d, etc. are exposed through openings 502a, 502b, 502c, 502d, etc. in the resist mask 502. The resist mask 502 is formed with widely known photolithography technology.

Returning to FIG. 7A, a p-type impurity is additionally ion implanted on the surface of the first surface preparatory layer 1180 through the opening 502a of the resist mask 502 to form a second surface layer 117 adjacent to the first surface layer 118. The implantation requirements for the p-type impurity during formation of the second surface layer 117 are as follows.

(1) Dose: 7E14/cm²

(2) Implantation energy: 3 key

(3) Implanted element: boron (B) or indium (In)

The second surface layer 117 is formed under the above-stated requirements, and the maximum concentration of the impurity becomes roughly 3E19/cm³.

Also, as shown in FIG. 7A, the interval g2 from the edge of the transfer gate electrode 120 to the edge of the opening 502a in the resist mask 502 is set at roughly 80 nm. This setting is based on consideration of the accuracy of formation of the resist mask 502, on the margin of implantation time of the p-type impurity, etc. This setting is adjusted to become the interval g1 (50 nm or more) from the transfer gate electrode 120 to the second surface layer 117, as shown in FIG. 5.

Next, as shown in FIG. 7B, after removing the resist mask 502, an FD low concentration n-type impurity preparatory region 1210 is formed as a structural element of the drain region in the transfer transistor 102 by implanting an n-type impurity inwards from the surface of the well region 112 in the region 10b.

After completion of the ion implantation, an insulating film (omitted from the figures) formed from a silicon oxide film, silicon nitride film, etc. is deposited on the entire main surface 110a above the semiconductor substrate 110 using the CVD method or other such method.

Next, as shown in FIG. 7C, an insulating film is formed so as to cover the entire upper part of region 10a and region 10b, and a resist mask 503 is deposited on top of the insulating film. The resist mask 503 has an opening so that part of the region 10b is exposed. Via photolithography or the like, etching is performed on the insulating film using reactive ion etching (RIE). In this way, a side wall 122 is formed on the side of the transfer gate electrode 120. At this point, since the region 10a is protected by the resist mask 503, an overlying film 124 is formed on the protected section. Note that the resist mask 503 on top of the overlying film 124 is removed by ashing or another method after formation of the side wall 122 is complete.

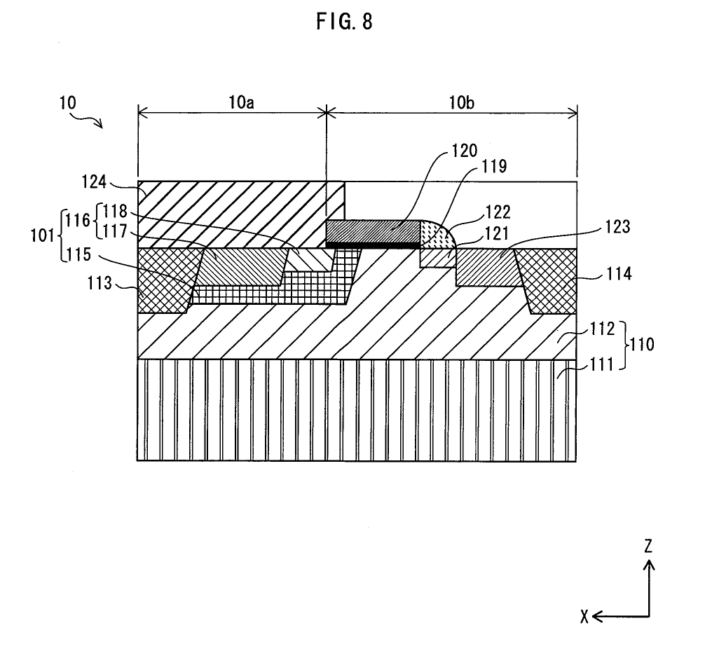

Afterwards, as shown in FIG. 8, arsenic (As), phosphorus (P), or antimony (Sb) is introduced onto the semiconductor substrate 110 in the region 10b by ion implantation or the like, thus forming an FD high concentration n-type impurity region 123 which constitutes the drain region of the transfer transistor 102. Note that by forming the FD high concentration n-type impurity region 123, the remaining part of the original FD low concentration n-type impurity preparatory region 1210 becomes the FD low concentration n-type impurity region 121.

Subsequently, activation annealing is performed at 850° C. for 10 minutes. An interlayer insulating film is thereby deposited on the entire main surface of the semiconductor substrate 110, and afterwards, a contact hole is formed above the transfer gate electrode 120 for the transfer transistor 102 and the FD high concentration n-type impurity region 123 (omitted from the figures). After the upper layer wiring is then formed, the solid state imaging device 1 is complete.

### 6. Confirmation of Advantages

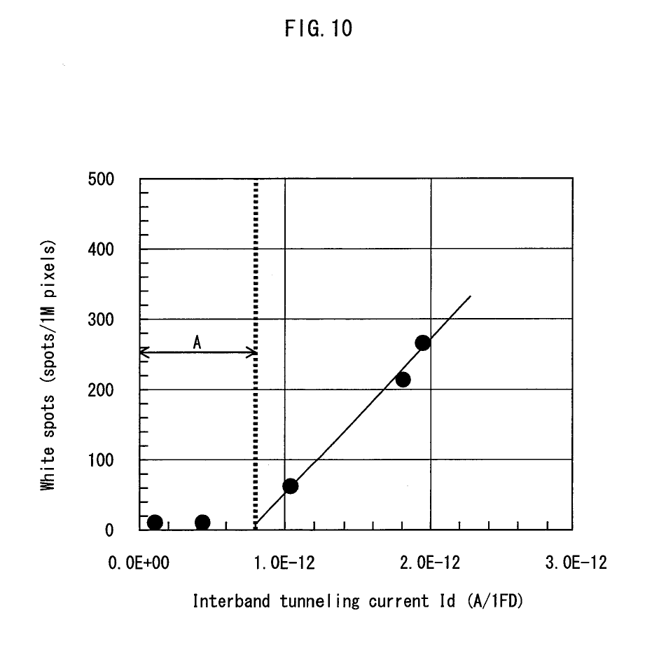

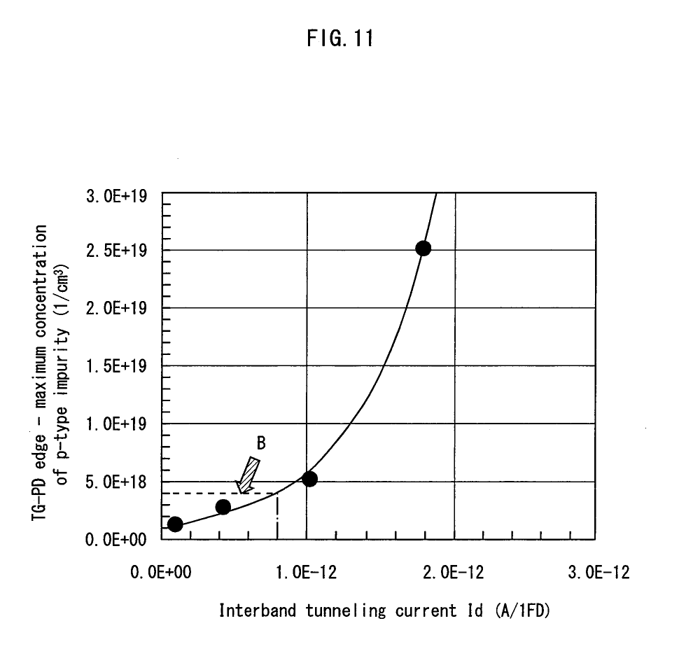

The advantages of the solid state imaging device 1 are described with reference to FIGS. 10 and 11, which are characteristic diagrams showing, under the following conditions, the relationship between interband tunneling current Id and the number of white spots and the relationship between interband tunneling current Id and concentration of impurity at the edge of the gate on the transfer transistor side.

Vs=3 V

Vg=4.1 V

In the solid state imaging device 1 according to the present embodiment, the surface layer 116 in the photodiode 101 is formed to have a second surface layer 117 with a relatively high concentration of a p-type impurity and a first surface layer 118 with a relatively low concentration of a p-type impurity. Also, the first surface layer 118 in the photodiode 101 is formed to overlap the transfer gate electrode 120 for the transfer transistor 102, and the second surface layer 117 is formed so that an interval g1 (see FIG. 5) exists between the second surface layer 117 and the transfer gate electrode 120. By adopting this sort of structure, the solid state imaging device 1 can reduce the number of white spots caused by interband tunneling current Id. In other words, as shown in FIG. 10, the number of white spots lowers as the interband tunneling current Id lowers. When the interband tunneling current Id was lowered below 8E-13 A/1FD, white spots were no longer observed (the region indicated by label A in FIG. 10).

As shown in FIG. 11, to lower the interband tunneling current ID, it is necessary to lower the concentration of the p-type impurity in the first surface layer 118 in the photodiode 101. However, in order to lower the interband tunneling current Id lower than 8E-13 A/1FD as described above, the concentration of the p-type impurity in the first surface layer 118 needs to be 4E18/cm³ or lower (the region indicated by label B in FIG. 11).

An overall consideration of the characteristic diagrams in both FIG. 10 and FIG. 11 indicates that when the gate voltage Vg of the transfer transistor 102 is 4.1 V, then by setting the concentration of the p-type impurity in the first surface layer 118 in the photodiode 101 at 4E18/cm³ or lower, the occurrence of white spots caused by interband tunneling current Id can be prevented.

Note that, while omitted from the figures, when the gate voltage Vg of the transfer transistor 102 is 3.3 V, then by setting the concentration of the p-type impurity in the first surface layer 118 in the photodiode 101 at 1E19/cm³, the occurrence of white spots caused by interband tunneling current Id can be prevented.

Furthermore, by setting the concentration of the p-type impurity in the first surface layer 118 in the photodiode 101 to 1E18/cm³ or greater in the solid state imaging device 1 according to the present embodiment, it has been confirmed that no increase in dark current caused by the impurity concentration in the first surface layer 118 is observed.

Next, in the solid state imaging device 1 according to the present embodiment, the second surface layer 117 is formed at a section removed from the transfer gate electrode 120 for the transfer transistor 102 by an interval g1. Also, as compared to the first surface layer 118, the concentration of the p-type impurity is set higher in the second surface layer 117. By adopting this sort of structure in the solid state imaging device 1, the concentration of the p-type impurity in the first surface layer 118, formed in the region overlapping the transfer gate electrode 120 for the transfer transistor 102, does not increase, and the depletion layer across the p-n junction of the photodiode 101 does not reach the surface of the semiconductor substrate 110. For this reason, the solid state imaging device 1 can suppress an increase in dark current.

Furthermore, in the solid state imaging device 1, the surface layer 116 of the photodiode 101 is formed from a combination of a first surface layer 118 with a low concentration of a p-type impurity and a second surface layer 117 with a high concentration of a p-type impurity. By adopting this sort of structure in the solid state imaging device 1, then as compared to when the surface layer 116 in the photodiode 101 consists only of a region with a low concentration of a p-type impurity, a reduction in the charge generation efficiency of the photodiode 101 can be suppressed. In other words, in the solid state imaging device 1, the resistance in the second surface layer 117 in the photodiode connected to the semiconductor substrate 110 can be reduced with the above-described structure, and electron-hole pair recombination of electrons generated in the depletion layer can be suppressed. Accordingly, in the solid state imaging device 1, the hole can be used effectively for emission towards the semiconductor substrate 110, and a reduction in the charge generation efficiency of the photodiode 101 can be suppressed.

In the solid state imaging device 1 according to the present embodiment, by setting the concentration of the p-type impurity in the second surface layer 117, which is formed at a position removed from the transfer gate electrode 120 for the transfer transistor 102 by an interval g1, at 2E19/cm³ or greater, an increase in dark current can be suppressed, and it was confirmed that the charge generation efficiency did not decrease.

As described above, in the solid state imaging device 1 according to the present embodiment, by adopting a structure that forms (i) a first surface layer 118 with a relatively low concentration of a p-type impurity on the section overlapping the transfer gate electrode 120 for the transfer transistor 102 and (ii) a second surface layer 117 with a relatively high concentration of a p-type impurity as compared to the first surface layer 118 at a position removed from the transfer gate electrode 120 for the transfer transistor 102 by an interval g1, the occurrence of dark current and white spots is suppressed, and S/N characteristics in the circuitry are high.

[Other]

Note that the structure of a solid state imaging device according to the present invention is not limited to the structure of the solid state imaging device 1 according to the above embodiment. A variety of modifications and adaptations are possible within the range of the effects produced by the present invention. The essential characteristics of the present invention are that, within a range in which white spots due to the occurrence of interband tunneling Id do not increase, a first surface layer 118 with a relatively low concentration of a p-type impurity is formed at a location overlapping the transfer gate electrode 120 for the transfer transistor 102, and within a range in which the depletion layer does not reach the surface of the semiconductor substrate 110, a second surface layer 117 with a relatively high concentration of a p-type impurity is formed in a section removed from the transfer transistor 102 by an interval g1.

For example, in the solid state imaging device 1 according to the above embodiment, the surface layer 116 in the photodiode 101 is formed from a combination of a first surface layer 118 and a second surface layer 117, but the surface layer of the photodiode may be formed from a combination of three of more surface layer elements. In this case as well, a structure would be adopted wherein a section overlapping the transfer gate electrode 120 would have a relatively lower concentration of impurity than the other sections.

Furthermore, in the solid state imaging device 1 according to the above embodiment, an example was provided wherein the charge accumulation layer 115 includes an n-type impurity, and the surface layer 116 includes a p-type impurity. A structure may be adopted, however, wherein the conductivity type of each impurity is reversed. Note that when reversing the conductivity type in this way, it is necessary to take into consideration the conductivity type of the well region 112 in the semiconductor substrate, etc.

Accordingly, the processes used in the above-described steps can be replaced by equivalent processes that do not depart from the range of the above technological concepts. It is also possible to change the order of the steps or the type of material.

Furthermore, while the present invention is particularly appropriate for an MOS solid state imaging device and the manufacturing thereof, the present invention may be applied to all solid state imaging elements that are provided with a photodiode and a transfer transistor. By endowing the surface layer of the photodiode with the same structure as the photodiode 101 in the solid state imaging device 1 according to the above embodiment, a highly sensitive solid state imaging device can be achieved.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

What is claimed is:

1. A solid state imaging device comprising:
a photodiode capable of photoelectric conversion and formed in a well region of a semiconductor substrate, the well region including an impurity of a first conductivity type; and
a transfer transistor capable of reading a charge from the photodiode and formed to have a transfer gate electrode above a surface of the well region with a gate insulating film therebetween, wherein
in the photodiode, a carrier accumulation layer and a surface layer are deposited in order from an inside towards a surface of the well region in a direction of thickness, the carrier accumulation layer including an impurity of a second conductivity type opposite to the first conductivity type and the surface layer including the impurity of the first conductivity type,
the transfer gate electrode partially overlaps the surface layer of the photodiode,
the surface layer includes a first surface layer that partially overlaps the transfer gate electrode and a second surface layer that does not overlap the transfer gate electrode,
the first surface layer and the second surface layer are adjacent to each other in a direction parallel to the surface of the well region, and
a concentration of the impurity of the first conductivity type is higher in the second surface layer than in the first surface layer.

2. The solid state imaging device in claim 1, wherein
in the first surface layer, the concentration of the impurity of the first conductivity type in the section overlapping the transfer gate electrode is in a range of 1E18/cm³ or greater and 1E19/cm³ or less.

3. The solid state imaging device in claim 1, wherein
in the second surface layer, a maximum concentration of the impurity of the first conductivity type is 2E19/cm³ or greater.

4. The solid state imaging device in claim 1, wherein
the second surface layer is formed at a distance of 50 nm or greater from the transfer gate electrode.

5. The solid state imaging device in claim 1, wherein
a depth of the second surface layer from the surface of the well region is greater than the first surface region.

6. A method of manufacturing a solid state imaging device comprising:
forming a well region by implanting an impurity of a first conductivity type inwards from one surface of a semiconductor substrate;
forming a carrier accumulation layer of a photodiode by implanting an impurity of a second conductivity type opposite to the first conductivity type inside the well region;
forming a transfer gate electrode of a transfer transistor above a surface of the well region so as to partially overlap the carrier accumulation layer;
forming a first surface layer of the photodiode by implanting the impurity of the first conductivity type inwards from a surface of the well region in which the carrier accumulation layer is formed, so that a section of the first surface layer is positioned under the transfer gate electrode; and
forming a second surface layer by implanting the impurity of the first conductivity type inwards from a surface of the well region in which the carrier accumulation layer is formed, so that the second surface layer does not overlap the transfer gate electrode and is adjacent to the first surface layer, wherein
a concentration of the impurity of the first conductivity type is higher in the second surface layer than in the first surface layer.

7. The method of manufacturing a solid state imaging device in claim 6, wherein
the impurity of the first conductivity type is implanted at a larger dose during the formation of the second surface layer than during the formation of the first surface layer.

8. The method of manufacturing a solid state imaging device in claim 6, wherein
the first surface layer is formed so that the concentration of the impurity of the first conductivity type in the section overlapping the transfer gate electrode is in a range of 1E18/cm³ or greater and 1E19/cm³ or less.

9. The method of manufacturing a solid state imaging device in claim 6, wherein
the second surface layer is formed so that a maximum concentration of the impurity of the first conductivity type is 2E19/cm³ or greater.

10. The method of manufacturing a solid state imaging device in claim 6, wherein
during formation of the first surface layer, the impurity of the first conductivity type is implanted in a preparatory region in which the second surface layer is to be formed, and
during formation of the second surface layer, the impurity of the first conductivity type is implanted again in the preparatory region.
